(19) United States
(12) Patent Application Publication
(10) Pub. No.: US 2024/0196582 A1
(43) Pub. Date: Jun. 13, 2024

(54) DIFFERENTIAL SIGNAL TRANSMISSION CABLE

(71) Applicant: SUMITOMO ELECTRIC INDUSTRIES, LTD., Osaka (JP)

(72) Inventors: Kengo GOTO, Osaka (JP); Takayuki ONISHI, Osaka (JP); Koji KASUYA, Osaka (JP); Kei HIRAI, Osaka (JP); Takashi SEKIYA, Osaka (JP); Yuji OCHI, Tochigi (JP); Yuto KOBAYASHI, Tochigi (JP)

(73) Assignee: SUMITOMO ELECTRIC INDUSTRIES, LTD., Osaka (JP)

(21) Appl. No.: 18/286,019

(22) PCT Filed: Jul. 1, 2021
(86) PCT No.: PCT/JP2021/024930

§ 371 Date: Oct. 6, 2023

(51) Int. Cl. H05K 9/00; H01B 11/00; H01B 13/22

(52) U.S. Cl. CPC H05K 9/0098; H01B 11/002; H01B 13/222

(57) ABSTRACT

A differential signal transmission cable includes: an insulating layer that extends in a longitudinal direction of the differential signal transmission cable; a pair of signal lines that extend in the longitudinal direction and are embedded in the insulating layer; and a shield layer that covers an outer peripheral surface of the insulating layer. The shield layer includes an electroless plating layer containing copper and alloy elements. The types and contents of the alloy elements are selected such that a tensile stress acts on the shield layer.

### TECHNICAL FIELD

The present disclosure relates to a differential signal transmission cable.

### BACKGROUND ART

PTL 1 (Japanese Patent Laying-Open No. 2019-16451) describes a differential signal transmission cable. The differential signal transmission cable described in PTL 1 includes an insulating layer, a pair of signal lines, and an electroless plating layer. The pair of signal lines is embedded in the insulating layer. The electroless plating layer is formed on the outer peripheral surface of the insulating layer.

### CITATION LIST

### Patent Literature

PTL 1: Japanese Patent Laying-Open No. 2019-16451

### SUMMARY OF INVENTION

The differential signal transmission cable according to the present disclosure includes: an insulating layer that extends in a longitudinal direction of the differential signal transmission cable; a pair of signal lines that extend in the longitudinal direction and are embedded in the insulating layer; and a shield layer that covers an outer peripheral surface of the insulating layer. The shield layer includes an electroless plating layer containing copper and alloy elements. The types and contents of the alloy elements are selected such that a tensile stress acts on the shield layer.

### BRIEF DESCRIPTION OF DRAWINGS

FIG. 1 is a perspective view of a cable 100.

FIG. 2 is a cross-sectional view of cable 100.

FIG. 3 is a partially enlarged view of FIG. 2 in a vicinity of an outer peripheral surface 10a.

FIG. 4 is a process chart showing a method of manufacturing cable 100.

FIG. 5 is a cross-sectional view of a processing target member 100A prepared in a preparation process S1.

FIG. 6 is a cross-sectional view of processing target member 100A after an intermediate layer forming process S2 is performed.

FIG. 7 is a cross-sectional view of processing target member 100A after a catalyst particle disposing process S3 is performed.

FIG. 8 is a cross-sectional view of processing target member 100A after an oxide layer forming process S4 and an electroless plating process S5 are performed.

### DETAILED DESCRIPTION

### Problem to be Solved by the Present Disclosure

When the differential signal transmission cable described in PTL 1 is bent, the electroless plating layer may be peeled off from the outer peripheral surface of the insulating layer. When the electroless plating layer peels off from the outer peripheral surface of the insulating layer due to bending, the transmission characteristics of the differential signal transmission cable deteriorate at the portion where the peeling occurs.

The present disclosure has been made in view of the problems of the above-described prior art. More specifically, the present disclosure provides a differential signal transmission cable capable of suppressing peeling of the shield layer from the outer peripheral surface of the insulating layer.

### Advantageous Effect of the Present Disclosure

According to the differential signal transmission cable of the present disclosure, it is possible to suppress peeling of the shield layer from the outer peripheral surface of the insulating layer.

### Description of Embodiments

First, embodiments of the present disclosure will be enumerated and described.

(1) A differential signal transmission cable according to a first aspect includes: an insulating layer that extends in a longitudinal direction of the differential signal transmission cable; a pair of signal lines that extend in the longitudinal direction and are embedded in the insulating layer; and a shield layer that covers an outer peripheral surface of the insulating layer. The shield layer includes an electroless plating layer containing copper and alloy elements. The types and contents of the alloy elements are selected such that a tensile stress acts on the shield layer.

According to the differential signal transmission cable of (1), it is possible to suppress peeling of the shield layer from the outer peripheral surface of the insulating layer.

(2) In the differential signal transmission cable according to (1), a content of copper in the shield layer may be greater than or equal to 90% by mass. The alloy elements may include at least one of nickel, iron, and cobalt. At least one of the following conditions may be satisfied: the content of nickel in the shield layer is greater than or equal to 0.10% by mass and less than or equal to 3.0% by mass; the content of iron in the shield layer is greater than or equal to 0.0010% by mass and less than or equal to 0.0050% by mass; and the content of cobalt in the shield layer is greater than or equal to 0.0010% by mass and less than or equal to 0.0050% by mass.

According to the differential signal transmission cable of (2), it is possible to stabilize a plating solution used for forming the electroless plating layer.

(3) The differential signal transmission cable according to (1) or (2) may further include a metal oxide layer between the insulating layer and the shield layer. In the metal oxide layer, a value obtained by dividing the atomic ratio of iron by the atomic ratio of copper may be greater than or equal to 0.000010 and less than or equal to 0.00010. In the metal oxide layer, a value obtained by dividing the atomic ratio of nickel by the atomic ratio of copper may be greater than or equal to 0.000050 and less than or equal to 0.00080. In the metal oxide layer, a value obtained by dividing the atomic ratio of cobalt by the atomic ratio of copper may be greater than or equal to 0.000010 and less than or equal to 0.00010.

According to the differential signal transmission cable of (3), it is possible to improve the adhesion of the shield layer.

(4) The differential signal transmission cable according to any one of (1) to (3) may further include catalyst particles between the insulating layer and the shield layer. The catalyst particles may contain palladium.

(5) The differential signal transmission cable according to any one of (1) to (4) may further include an intermediate layer that covers an outer peripheral surface of the insulating layer. The shield layer may cover an outer peripheral surface of the intermediate layer.

(6) A differential signal transmission cable according to a second aspect of the present disclosure includes: an insulating layer that extends in a longitudinal direction of the differential signal transmission cable; a pair of signal lines that extend in the longitudinal direction and are embedded in the insulating layer; and a shield layer that covers an outer peripheral surface of the insulating layer. The hardness of the insulating layer is greater than or equal to 0.020 GPa. The hardness of the shield layer is less than or equal to 4.0 GPa.

According to the differential signal transmission cable of (6), it is possible to suppress peeling of the shield layer from the outer peripheral surface of the insulating layer.

(7) In the differential signal transmission cable according to (6), a value obtained by dividing the hardness of the shield by the hardness of the insulating layer may be greater than or equal to 20 and less than or equal to 100.

(8) In the differential signal transmission cable according to (6) or (7), in a cross section orthogonal to the longitudinal direction, the insulating layer may have a first portion that is a portion at a distance of up to 50 m from the outer peripheral surface of each of the pair of signal lines and a second portion that is a portion at a distance of up to 50 μm from the outer peripheral surface of the insulating layer. A value obtained by dividing the hardness of the first portion by the hardness of the second portion may be greater than or equal to 1.05 and less than or equal to 1.50.

According to the differential signal transmission cable of (8), it is possible to make the differential signal transmission cable easily bendable.

(9) A differential signal transmission cable according to a third aspect of the present disclosure includes: an insulating layer that extends in a longitudinal direction of the differential signal transmission cable; a pair of signal lines that extend in the longitudinal direction and are embedded in the insulating layer; and a shield layer that covers an outer peripheral surface of the insulating layer. The shield layer contains copper. The crystallite size of copper in the shield layer is greater than or equal to 20 nm and less than or equal to 75 nm.

According to the differential signal transmission cable of (10), it is possible to suppress peeling of the shield layer from the outer peripheral surface of the insulating layer.

### Details of Embodiments

Next, details of the embodiments of the present disclosure will be described with reference to the drawings. In the following drawings, the same or corresponding portions are denoted by the same reference numeral, and redundant description will not be repeated.

### (Configuration of Differential Signal Transmission Cable According to Embodiment)

Hereinafter, a configuration of a differential signal transmission cable according to an embodiment will be described. The differential signal transmission cable according to the embodiment is referred to as a cable 100.

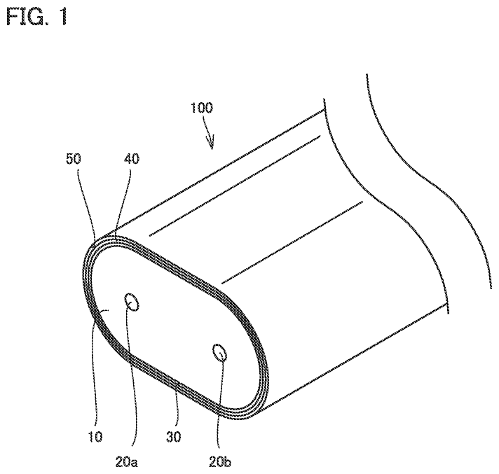

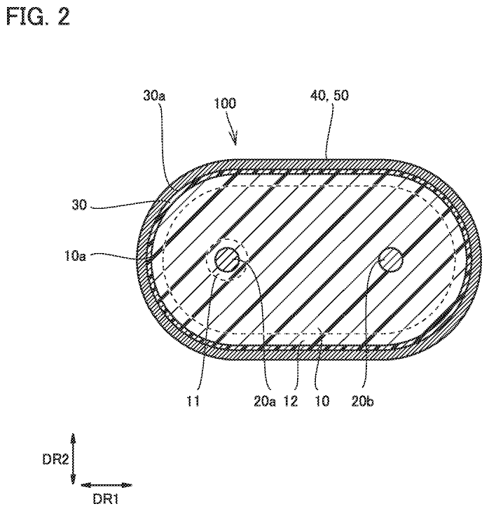

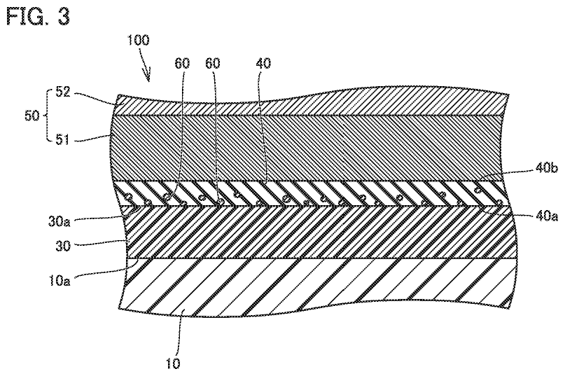

FIG. 1 is a perspective view of cable 100. FIG. 2 is a cross-sectional view of cable 100. FIG. 2 shows a cross section orthogonal to the longitudinal direction of cable 100. FIG. 3 is a partially enlarged view of FIG. 2 in a vicinity of an outer peripheral surface 10a. As shown in FIGS. 1, 2, and 3, cable 100 includes an insulating layer 10, a signal line 20a, a signal line 20b, an intermediate layer 30, a metal oxide layer 40, a shield layer 50, and catalyst particles 60.

Insulating layer 10 extends in the longitudinal direction of cable 100. Insulating layer 10 is formed of an electrically insulating material. Insulating layer 10 is formed of, for example, polyethylene (PE), tetrafluoroethylene-hexafluoropropylene copolymer (FEP), polypropylene (PP), cyclic olefin polymer, or polymethylpentene. Insulating layer 10 may be a layer containing one or a plurality of these materials. It is preferable that the hardness of insulating layer 10 is greater than or equal to 0.020 GPa. The hardness of insulating layer 10 may be greater than or equal to 0.0035 GPa.

Directions orthogonal to the longitudinal direction of cable 100 are referred to as a first direction DR1 and a second direction DR2. First direction DR1 and second direction DR2 are orthogonal to each other. In a cross-sectional view orthogonal to the longitudinal direction of cable 100, insulating layer 10 has, for example, an elliptical shape whose long axis extends in first direction DR1.

Insulating layer 10 has outer peripheral surface 10a. insulating layer 10 includes a first portion 11 and a second portion 12. First portion 11 is a portion at a distance of up to 50 μm from the outer peripheral surface of signal line 20a (signal line 20b). Second portion 12 is a portion at a distance of up to 50 μm from outer peripheral surface 10a. It is preferable that the hardness of second portion 12 is lower than the hardness of first portion 11. It is preferable that a value obtained by dividing the hardness of first portion 11 by the hardness of the second portion is greater than or equal to 1.05 and less than or equal to 1.50.

The hardness of insulating layer 10 (first portion 11, second portion 12) is measured using a TriboIndenter Hysitron T1980 manufactured by Bruker. In this measurement, a Berkovich indenter is used as an indenter. The maximum load is 8 mN. The loading time is 5 seconds. The maximum load hold time is 0 seconds. This measurement is performed at 25° C. in air. The analysis by TI980 is performed using TribScan, which is the dedicated software for TI980. This measurement is performed on a sample embedded in an epoxy resin and subjected to mirror polishing.

Signal line 20a and signal line 20b form a pair. A signal having an opposite phase to the signal applied to signal line 20a is applied to signal line 20b. Thus, cable 100 transmits a differential signal.

Signal line 20a and signal line 20b are embedded in insulating layer 10. Signal line 20a and signal line 20b extend in the longitudinal direction of cable 100. Signal line 20a and signal line 20b are formed of a conductive material. Signal line 20a and signal line 20b are formed of, for example, copper (Cu). However, the material constituting signal line 20a and signal line 20b is not limited to copper. Signal line 20a and signal line 20b are arranged in first direction DR1, for example.

Intermediate layer 30 covers outer peripheral surface 10a. Intermediate layer 30 has an outer peripheral surface 30a. Intermediate layer 30 is formed of an electrically insulating material. Intermediate layer 30 is formed of, for example, polyolefin. Intermediate layer 30 may be formed of acrylonitrile butadiene styrene resin (ABS resin).

Metal oxide layer 40 is a layer of metal oxide. Metal oxide layer 40 mainly contains copper oxide (CuO). However, metal oxide layer 40 may contain an element other than copper and oxygen. Metal oxide layer 40 may further contain, for example, at least one of nickel (Ni), iron (Fe), and cobalt (Co).

The atomic ratio of copper in metal oxide layer 40 is represented by A (unit: atomic percent). The atomic ratio of iron in the metal oxide layer is represented by B (unit: atomic percent). The atomic ratio of nickel in metal oxide layer 40 is represented by C (unit: atomic percent). The atomic ratio of cobalt in metal oxide layer 40 is represented by D (unit: atomic percent). It is preferable that the value obtained by dividing B by A is greater than or equal to 0.000010 and less than or equal to 0.00010. It is preferable that the value obtained by dividing C by A is greater than or equal to 0.000050 and less than or equal to 0.00080. It is preferable that the value obtained by dividing D by A is greater than or equal to 0.000010 and less than or equal to 0.00010. The values of A, B, C, and D are measured using EDX (Energy Dispersive X-ray spectroscopy).

Metal oxide layer 40 covers outer peripheral surface 30a. It is preferable that metal oxide layer 40 covers outer peripheral surface 30a over the entire periphery. However, metal oxide layer 40 may not cover a part of outer peripheral surface 30a. In this case, a part of outer peripheral surface 30a that is not covered with metal oxide layer 40 is in contact with shield layer 50.

Metal oxide layer 40 has a first surface 40a and a second surface 40b. First surface 40a is a surface facing the side of intermediate layer 30. Second surface 40b is a surface opposite to first surface 40a. Second surface 40b faces the side of shield layer 50. Metal oxide layer 40 is in contact with intermediate layer 30 on first surface 40a, and is in contact with shield layer 50 on second surface 40b.

Shield layer 50 covers second surface 40b. That is, shield layer 50 covers outer peripheral surface 10a with intermediate layer 30 and metal oxide layer 40 interposed therebetween. Shield layer 50 has conductivity.

Shield layer 50 includes, for example, an electroless plating layer 51 and an electrolytic plating layer 52. Electroless plating layer 51 covers metal oxide layer 40. Electrolytic plating layer 52 covers electroless plating layer 51.

Electroless plating layer 51 is a layer formed by electroless plating. Electroless plating layer 51 contains copper. Electroless plating layer 51 further contains alloy elements. The types and contents of the alloy elements are selected so as to generate a tensile stress in shield layer 50. The alloy elements are, for example, elements that form a solid solution with copper. More specifically, the alloy elements include at least one of iron, nickel, and cobalt. However, the alloy elements are not limited to iron, nickel and cobalt. Electrolytic plating layer 52 is a layer formed by electrolytic plating. Electrolytic plating layer 52 contains, for example, copper.

Since electroless plating layer 51 contains the above-described alloy elements, the above-described alloy elements form a solid solution with the copper in electroless plating layer 51, and distortion occurs in a crystal of the copper in electroless plating layer 51. In addition, the crystallinity of electrolytic plating layer 52 reflects the crystallinity of electroless plating layer 51, and thus, distortion also occurs in electrolytic plating layer 52 because electroless plating layer 51 contains the above-described alloy elements. Due to such distortion, the tensile stress remains in shield layer 50.

The content of copper in shield layer 50 is, for example, greater than or equal to 90% by mass. It is preferable that the content of iron in shield layer 50 is greater than or equal to 0.0010% by mass and less than or equal to 0.0050% by mass. It is preferable that the content of nickel in shield layer 50 is greater than or equal to 0.10% by mass and less than or equal to 3.0% by mass. It is preferable that the content of cobalt in shield layer 50 is greater than or equal to 0.0010% by mass and less than or equal to 0.0050% by mass. Preferably, at least one of the following conditions is satisfied: the content of nickel in shield layer 50 is greater than or equal to 0.10% by mass and less than or equal to 3.0% by mass; the content of iron in shield layer 50 is greater than or equal to 0.0010% by mass and less than or equal to 0.0050% by mass; and the content of cobalt in shield layer 50 is greater than or equal to 0.0010% by mass and less than or equal to 0.0050% by mass. The contents of copper, iron, nickel, and cobalt in shield layer 50 are measured by dissolving shield layer 50 in a solution and performing ICP (Inductive Coupled Plazma) emission spectrometry on the solution.

It is preferable that the hardness of shield layer 50 is less than or equal to 4.0 GPa. It is preferable that the value obtained by dividing the hardness of shield layer 50 by the hardness of insulating layer 10 is greater than or equal to 20 and less than or equal to 100.

The hardness of shield layer 50 is measured using the TripoIndenter Hysitron TI980 manufactured by Bruker. In this measurement, a Berkovich indenter is used as an indenter. The maximum load is 30 μN. The loading time is 2 seconds. The maximum load hold time is 2 seconds. This measurement is performed at 25° C. in air. The analysis by TI980 is performed using TribScan, which is the dedicated software for TI980. This measurement is performed on a sample embedded in an epoxy resin and subjected to mirror polishing.

It is preferable that the crystallite size of copper in shield layer 50 is greater than or equal to 20 nm and less than or equal to 75 nm. It is more preferable that the crystallite size of copper in shield layer 50 is greater than or equal to 20 nm and less than or equal to 60 nm. Shield layer 50 contains crystal grains of copper. The portion of a crystal grain that can be regarded as a single crystal is referred to as a crystallite. Therefore, the crystallite size of copper in shield layer 50 is less than or equal to the grain size of the crystal grains of copper contained in shield layer 50.

The crystallite size of copper in shield layer 50 can be measured using an X-ray diffraction method. More specifically, the X-ray diffraction is performed using a SmartLab manufactured by Rigaku. In this measurement, the X-ray source is CuKα, the incident light source is CBO-f, and the detector is Hypix-3000. The X-ray diffraction is performed at a diffraction angle 2θ in a range of 20° to 80° inclusive with a step of changing the diffraction angle 2θ by 0.03°.

A line profile obtained by X-ray diffraction on a sample has a shape including both a true spread caused by a physical quantity of a crystallite size of the sample and a spread caused by a measuring apparatus. In order to determine the crystallite size, a component caused by the apparatus is removed from the line profile obtained by X-ray diffraction on the sample, and an integral width of a true line profile (a value obtained by dividing an integral intensity of a peak by a height of the peak) is calculated. By substituting the integral width of the true line profile into the Scherrer equation, the crystallite size of the sample is obtained.

LaB₆ manufactured by NIST is used as a standard sample for removing the component caused by the apparatus from the line profile obtained by X-ray diffraction on the sample. The integral width of the true line profile is β, the integral width of the line profile obtained by X-ray diffraction on the sample is β₁, and the integral width of the line profile obtained by X-ray diffraction on a standard sample is β₂. The relation among β, β₁ and β₂ is expressed by β²=β₁²−β₂² (Equation 1). The Scherrer equation is expressed by D=Kλ/β cos θ (Equation 2). Here, D is the crystallite size of the sample, K is the Scherrer constant (K=1.33), λ is the wavelength of the X-ray, and θ is the Bragg angle of the Cu200 diffraction line. By substituting β obtained from Equation 1 into Equation 2, the value of D, i.e., the crystallite size of the sample, is obtained.

Catalyst particles 60 are between insulating layer 10 and shield layer 50. More specifically, shield layer 50 is in metal oxide layer 40. Catalyst particles 60 are also present at the interface between metal oxide layer 40 and intermediate layer 30. Catalyst particles 60 are, for example, particles containing palladium (Pd).

### (Method of Manufacturing Differential Signal Transmission Cable According to Embodiment)

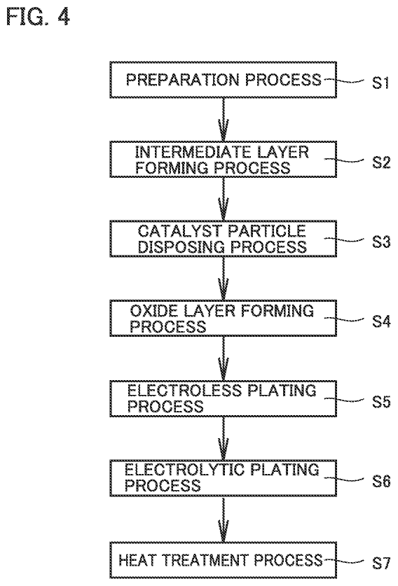

Hereinafter, a method of manufacturing cable 100 will be described. FIG. 4 is a process chart showing the method of manufacturing cable 100. As shown in FIG. 4, the method of manufacturing cable 100 includes a preparation process S1, an intermediate layer forming process S2, a catalyst particle disposing process S3, an oxide layer forming process S4, an electroless plating process S5, an electrolytic plating process S6, and a heat treatment process S7.

After preparation process S1, intermediate layer forming process S2 is performed. After intermediate layer forming process S2, catalyst particle disposing process S3 is performed. After catalyst particle disposing process S3, oxide layer forming process S4 is performed. After oxide layer forming process S4, electroless plating process S5 is performed. After electroless plating process S5, electrolytic plating process S6 is performed. After electrolytic plating process S6, heat treatment process S7 is performed.

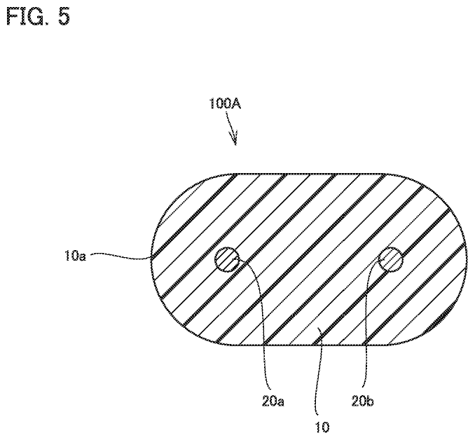

In preparation process S1, processing target member 100A is prepared. FIG. 5 is a cross-sectional view of processing target member 100A prepared in preparation process S1. As shown in FIG. 5, processing target member 100A includes insulating layer 10, signal line 20a, and signal line 20b.

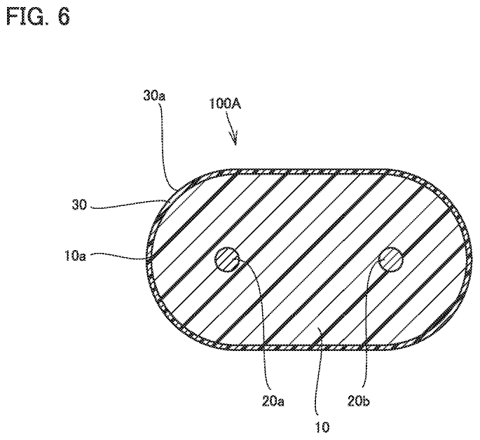

FIG. 6 is a cross-sectional view of processing target member 100A after intermediate layer forming process S2 is performed. As shown in FIG. 6, in intermediate layer forming process S2, intermediate layer 30 is formed in a manner of covering outer peripheral surface 10a. In intermediate layer forming process S2, a material constituting intermediate layer 30 is applied to outer peripheral surface 10a and the applied material is cured to form intermediate layer 30 in a manner of covering outer peripheral surface 10a.

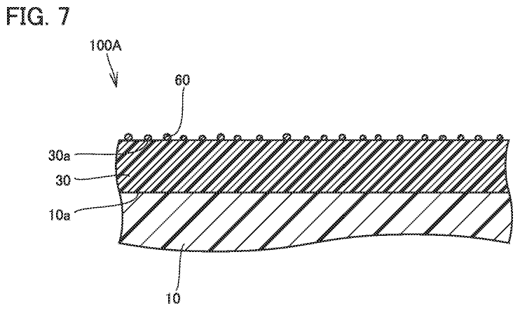

FIG. 7 is a cross-sectional view of processing target member 100A after catalyst particle disposing process S3 is performed. As shown in FIG. 7, in catalyst particle disposing process S3, catalyst particles 60 are dispersedly disposed on outer peripheral surface 30a. In catalyst particle disposing process S3, catalyst particles 60 are dispersedly disposed on outer peripheral surface 30a by applying a solution containing catalyst particles 60 to outer peripheral surface 30a and volatilizing the solution.

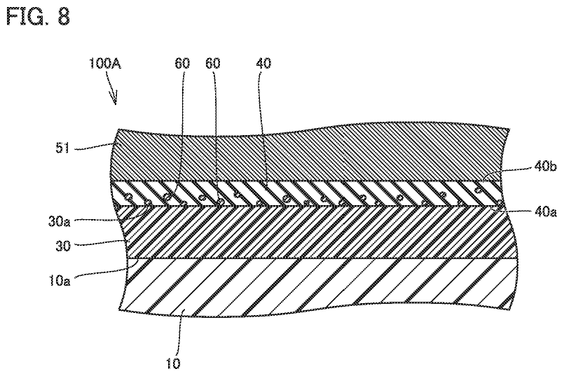

FIG. 8 is a cross-sectional view of processing target member 100A after oxide layer forming process S4 and electroless plating process S5 are performed. As shown in FIG. 8, metal oxide layer 40 is formed in oxide layer forming process S4, and electroless plating layer 51 is formed on metal oxide layer 40 in electroless plating process S5.

In oxide layer forming process S4, processing target member 100A is immersed in a plating solution in which a material contained in electroless plating layer 51 is dissolved and an oxygen-containing gas (for example, air) is bubbled. Thus, metal oxide layer 40 is formed in a manner of covering outer peripheral surface 30a with catalyst particles 60 as nuclei. Among catalyst particles 60, those which serve as nuclei for the growth of metal oxide layer 40 are present in metal oxide layer 40, and the other catalyst particles are present at the interface between intermediate layer 30 and metal oxide layer 40. By adding alloy elements such as iron, nickel, and cobalt to the plating solution, these alloy elements are contained in metal oxide layer 40.

In electroless plating process S5, the above-described bubbling is stopped. As a result, electroless plating layer 51 is plated on metal oxide layer 40.

In electrolytic plating process S6, electrolytic plating layer 52 is formed in a manner of covering electroless plating layer 51. In electrolytic plating process S6, processing target member 100A is immersed in a plating solution in which a material contained in electrolytic plating layer 52 is dissolved, and electroless plating layer 51 is energized. As a result, electrolytic plating layer 52 is plated on electroless plating layer 51, and cable 100 having the structure shown in FIGS. 1 to 3 is manufactured.

In heat treatment process S7, heat treatment is performed on cable 100. By the heat treatment, the crystal grains of copper contained in shield layer 50 grow, and the crystallite size in shield layer 50 also increases accordingly. Since the hardness of shield layer 50 decreases as the grain size of the crystal grains of copper contained in shield layer 50 increases (Hall-Petch rule), the heat treatment decreases the hardness of shield layer 50. In addition, since the crystallization of the resin material constituting insulating layer 10 proceeds by the heat treatment, the hardness of insulating layer 10 increases with the heat treatment.

### (Effects of Differential Signal Transmission Cable According to Embodiment)

Hereinafter, effects of cable 100 will be described.

Cable 100 may be used in a bent state. Compressive bending stress acts on shield layer 50 on the inner side of cable 100 which is in the bent state. Due to the compressive bending stress, shield layer 50 may be buckled and peeled off from insulating layer 10 which is on the inner side of cable 100 which is in the bent state. When such peeling occurs, the transmission characteristics of cable 100 deteriorate.

However, in cable 100, electroless plating layer 51 contains alloy elements, and thus, a tensile stress acts on shield layer 50. Thus, according to cable 100, the compressive stress applied to shield layer 50 on the inner side of cable 100 which is in the bent state is relaxed and the peeling accompanying the buckling of shield layer 50 is suppressed, and thus, it is possible to suppress the deterioration of the transmission characteristics of cable 100 when cable 100 is bent.

Since the plating solution used for forming electroless plating layer 51 is chemically unstable, it is difficult to handle the plating solution. As described above, when electroless plating layer 51 contains at least one of iron and nickel, these elements are added to the plating solution used for forming electroless plating layer 51. The addition of iron, nickel, and cobalt chemically stabilizes the plating solution used for forming electroless plating layer 51. Therefore, when electroless plating layer 51 contains at least one of iron, nickel, and cobalt, it is possible to stabilize the manufacturing process of cable 100.

In order to ensure the adhesion of shield layer 50 to insulating layer 10, it is conceivable to roughen outer peripheral surface 10a to enhance the anchor effect between shield layer 50 and insulating layer 10. However, when outer peripheral surface 10a is roughened, transmission characteristics of cable 100 in a high-frequency region deteriorate.

Cable 100 includes metal oxide layer 40, and hydrogen bonding occurs between shield layer 50 (electroless plating layer 51) and metal oxide layer 40. The hydrogen bonding ensures the adhesion between metal oxide layer 40 and shield layer 50, and as a result, the adhesion between insulating layer 10 and shield layer 50 is ensured without roughening outer peripheral surface 10a. Thus, it is possible to ensure the adhesion of shield layer 50 to insulating layer 10 while ensuring the transmission characteristics of cable 100 in the high-frequency region when cable 100 includes metal oxide layer 40.

When the hardness of insulating layer 10 is low, insulating layer 10 on the inner side of cable 100 which is in the bent state is recessed toward the inside of cable 100. In addition, when the hardness of shield layer 50 is high, shield layer 50 on the inner side of cable 100 which is in the bent state is bent toward the inside of cable 100. Thus, when the difference between the hardness of insulating layer 10 and the hardness of shield layer 50 becomes large, wrinkles are generated on the inner side of cable 100 when cable 100 is bent, and the transmission characteristics deteriorate.

In cable 100, the hardness of insulating layer 10 is greater than or equal to 0.020 GPa and the hardness of shield layer 50 is less than or equal to 4.0 GPa, and thus, the difference between the hardness of insulating layer 10 and the hardness of shield layer 50 becomes small, and it is possible to suppress deterioration of the transmission characteristics when cable 100 is bent. In a case where the value obtained by dividing the hardness of shield layer 50 by the hardness of insulating layer 10 is greater than or equal to 20 and less than or equal to 100, it is possible to further suppress deterioration of the transmission characteristics when cable 100 is bent.

In a case where the crystallite size of copper in shield layer 50 is greater than or equal to 20 nm and less than or equal to 75 nm, the hardness of shield layer 50 can also be reduced, and thus, similarly, it is possible to further suppress deterioration of the transmission characteristics when cable 100 is bent.

In cable 100, when the value obtained by dividing the hardness of first portion 11 by the hardness of second portion 12 is greater than or equal to 1.05 and less than or equal to 1.50, the cross-sectional secondary moment of insulating layer 10 becomes smaller, and the deformation of insulating layer 10 can easily follow the deformation of cable 100. Therefore, in this case, insulating layer 10 is less likely to be peeled off from signal line 20a (signal line 20b) when cable 100 is bent.

### (First Loss Evaluation Test)

In a first loss evaluation test, the relation between the contents of the alloy elements in shield layer 50 (electroless plating layer 51) and the transmission characteristics of cable 100 is evaluated. In the first loss evaluation test, samples 1-1 to 1-9 are provided as samples of cable 100. As shown in Table 1, in samples 1-1 to 1-9, the contents of nickel, iron, and cobalt in shield layer 50 vary. Although not shown in Table 1, in samples 1-1 to 1-9, the content of copper in shield layer 50 is greater than or equal to 90% by mass.

TABLE 1

| | | | | Differential-mode | | |
|---|---|---|---|---|---|---|
| | | | | transmission loss (dB/m) | | |
| | Content in shield layer 50 (% by mass) | | | Before | After | |
| | Fe | Ni | Co | bending | bending | Evaluation |
| Sample 1-1 | Less than 0.001 | 0.11 | Less than 0.001 | −20 | −21 | OK |
| Sample 1-2 | 0.005 | 0.08 | 0.001 | −21 | −20 | OK |
| Sample 1-3 | 0.042 | 0.28 | 0.002 | −23 | −22 | OK |
| Sample 1-4 | Less than 0.001 | 0.08 | 0.003 | −20 | −20 | OK |
| Sample 1-5 | 0.005 | 0.07 | 0.005 | −21 | −21 | OK |
| Sample 1-6 | 0.002 | 0.11 | 0.003 | −19 | −20 | OK |
| Sample 1-7 | 0.004 | 0.29 | 0.004 | −21 | −20 | OK |
| Sample 1-8 | 0.08 | 0.07 | Less than 0.001 | −21 | −31 | NG |
| Sample 1-9 | Less than 0.001 | 0.08 | Less than 0.001 | −21 | −30 | NG |

In the first loss evaluation test, the transmission characteristics are evaluated by measuring the differential-mode insertion loss of each sample in a state in which each sample is wound around a cylinder having a diameter of 50 mm. A case where there is no difference in the differential-mode insertion loss before and after the winding or a case where the differential-mode insertion loss is greater than or equal to −25 dB/m after the winding is evaluated as OK, and a case where the differential-mode insertion loss is less than −25 dB/m after the winding is evaluated as NG.

A condition 1 is that the content of nickel in shield layer 50 is greater than or equal to 0.10% by mass and less than or equal to 3.0% by mass; a condition 2 is that the content of iron in shield layer 50 is greater than or equal to 0.0010% by mass and less than or equal to 0.0050% by mass; and a condition 3 is that the content of cobalt in shield layer 50 is greater than or equal to 0.0010% by mass and less than or equal to 0.0050% by mass.

In samples 1-1 to 1-7, at least one of conditions 1 to 3 is satisfied. On the other hand, none of conditions 1 to 3 is satisfied in sample 1-8 and sample 1-9. In each of samples 1-1 to 1-7, the transmission characteristics are evaluated as OK. On the other hand, in each of sample 1-8 and sample 1-9, the transmission characteristics are evaluated as NG. Based on this comparison, it has been experimentally revealed that the deterioration of the transmission characteristics associated with the bending of cable 100 can be suppressed by satisfying at least one of conditions 1 to 3.

### (Second Loss Evaluation Test)

In the second loss evaluation test, the relation between the hardnesses of shield layer 50 and insulating layer 10 and the transmission characteristics of cable 100 is evaluated. In the second loss evaluation test, samples 2-1 to 2-3 are provided as samples of cable 100. As shown in Table 2, in samples 2-1 to 2-3, the atomic ratios of copper, nickel, iron, and cobalt in shield layer 50 vary. Accordingly, in samples 2-1 to 2-3, the value obtained by dividing B by A, the value obtained by dividing C by A, and the value obtained by dividing D by A vary.

TABLE 2

| | | | | | | | | | | | Differential-mode | | |
|---|---|---|---|---|---|---|---|---|---|---|---|---|---|
| | | | | | | | | | | | transmission loss (dB/m) | | |
| | Atomic ratio in metal oxide layer 40 (% by atom) | | | | | | | | | | Before | After | |
| | Cu | Fe | Ni | Co | C | O | Pd | B/A | C/A | D/A | bending | bending | Evaluation |
| Sample 2-1 | 68.3 | 0.001 | 0.008 | 0.001 | 10.02 | 21.6 | 0.002 | 0.000013 | 0.000120 | 0.000012 | −20 | −21 | OK |
| Sample 2-2 | 81.1 | 0.005 | 0.028 | 0.005 | 10.38 | 8.5 | 0.002 | 0.000060 | 0.000341 | 0.000057 | −21 | −20 | OK |
| Sample 2-3 | 71.2 | 0.0005 | 0.002 | 0.0006 | 8.20 | 20.6 | 0.002 | 0.000007 | 0.000028 | 0.000008 | −20 | −30 | NG |

In the second loss evaluation test, the transmission characteristics of each sample are evaluated by the same method as in the first loss evaluation test. A condition 4 is that the value obtained by dividing B by A is greater than or equal to 0.000010 and less than or equal to 0.00010, a condition 5 is that the value obtained by dividing C by A is greater than or equal to 0.000010 and less than or equal to 0.00080, and a condition 6 is that the value obtained by dividing D by A is greater than or equal to 0.000010 and is less than or equal to 0.00010.

In sample 2-1 and sample 2-2, all of conditions 4 to 6 are satisfied. On the other hand, condition 5 is not satisfied in sample 2-3. In each of samples 2-1 and 2-2, the transmission characteristics are evaluated as OK. On the other hand, in sample 2-3, the transmission characteristics are evaluated as NG. Based on this comparison, it has been experimentally revealed that the deterioration of the transmission characteristics associated with the bending of cable 100 can be suppressed by satisfying any one of conditions 4 to 6.

### (Third Loss Evaluation Test)

In the third loss evaluation test, the relation between the hardnesses of shield layer 50 and insulating layer 10 and the transmission characteristics of cable 100 is evaluated. In the third loss evaluation test, samples 3-1 to 3-11 are provided as samples of cable 100. As shown in Table 3, in samples 3-1 to 3-11, the type of the material constituting insulating layer 10, the hardness of insulating layer 10, and the hardness of shield layer 50 vary. The hardness of shield layer 50 is adjusted by performing the heat treatment shown in Table 3.

TABLE 3

| | | | | | Hardness of | Differential-mode | | |
|---|---|---|---|---|---|---|---|---|
| | Insulating layer 10 | | Shield layer 50 | | shield layer 50/ | transmission loss (dB/m) | | |
| | Type of | Hardness | | Hardness | hardness of | Before | After | |
| | material | (GPa) | Heat treatment | (GPa) | insulating layer 10 | bending | bending | Evaluation |
| Sample 3-1 | PP | 0.072 | 3 minutes at 50° C. | 3.7 | 51 | −21 | −20 | OK |
| Sample 3-2 | PP | 0.067 | 3 minutes at 80° C. | 2.8 | 42 | −20 | −21 | OK |
| Sample 3-3 | PP | 0.070 | 3 minutes at 100° C. | 2.5 | 36 | −20 | −19 | OK |
| Sample 3-4 | PP | 0.068 | 3 minutes at 120° C. | 2.5 | 37 | −20 | −20 | OK |
| Sample 3-5 | FEP | 0.055 | 3 minutes at 50° C. | 3.6 | 65 | −20 | −21 | OK |
| Sample 3-6 | FEP | 0.052 | 3 minutes at 80° C. | 2.7 | 52 | −21 | −21 | OK |
| Sample 3-7 | FEP | 0.054 | 3 minutes at 100° C. | 2.5 | 46 | −21 | −20 | OK |
| Sample 3-8 | FEP | 0.052 | 3 minutes at 120° C. | 2.5 | 48 | −21 | −20 | OK |
| Sample 3-9 | PP | 0.078 | N/A | 4.2 | 54 | −20 | −25 | OK |
| Sample 3-10 | FEP | 0.055 | N/A | 4.3 | 78 | −20 | −25 | OK |
| Sample 3-11 | PE | 0.026 | N/A | 4.1 | 158 | −20 | −35 | NG |

In the third loss evaluation test, the transmission characteristics of each sample are evaluated by the same method as in the first loss evaluation test. In samples 3-1 to 3-10, the value obtained by dividing the hardness of shield layer 50 by the hardness of insulating layer 10 is in a range of greater than or equal to 20 and less than or equal to 100. On the other hand, in sample 3-11, the value obtained by dividing the hardness of shield layer 50 by the hardness of insulating layer 10 is not in the range of greater than or equal to 20 and less than or equal to 100. In each of samples 3-1 to 3-10, the transmission characteristics are evaluated as OK. On the other hand, in sample 3-11, the transmission characteristics are evaluated as NG. Based on this comparison, it has been experimentally revealed that the deterioration of the transmission characteristics associated with the bending of cable 100 can be suppressed by setting the value obtained by dividing the hardness of shield layer 50 by the hardness of insulating layer 10 to be greater than or equal to 20 and less than or equal to 100.

### (Fourth Loss Evaluation Test)

In the fourth loss evaluation test, the relation between the hardnesses of shield layer 50 and insulating layer 10 and the transmission characteristics of cable 100 is evaluated. In the fourth loss evaluation test, samples 4-1 to 4-3 are provided as samples of cable 100. As shown in Table 4, in samples 4-1 to 4-3, the type of the material constituting insulating layer 10, the hardness of first portion 11, and the hardness of second portion 12 vary.

TABLE 4

| | Insulating layer 10 | | | | | | |
|---|---|---|---|---|---|---|---|
| | | | | Hardness of | Differential-mode | | |
| | | Hardness of | Hardness of | first portion 11/ | transmission loss (dB/m) | | |
| | Type of | first portion | second portion | hardness of | Before | After | |
| | material | 11 (GPa) | 12 (GPa) | second portion 12 | bending | bending | Evaluation |
| Sample 4-1 | PP | 0.072 | 0.053 | 1.36 | −21 | −20 | OK |
| Sample 4-2 | FEP | 0.055 | 0.047 | 1.17 | −20 | −20 | OK |
| Sample 4-3 | PP | 0.072 | 0.071 | 1.01 | −20 | −27 | NG |

In the fourth loss evaluation test, the transmission characteristics of each sample are evaluated by the same method as in the first loss evaluation test. In sample 4-1 and sample 4-2, the value obtained by dividing the hardness of first portion 11 by the hardness of second portion 12 is in a range of greater than or equal to 1.05 and less than or equal to 1.50. On the other hand, in sample 4-3, the value obtained by dividing the hardness of first portion 11 by the hardness of second portion 12 is not in the range of greater than or equal to 1.05 and less than or equal to 1.50. In each of samples 4-1 and 4-2, the transmission characteristics are evaluated as OK. On the other hand, in sample 4-3, the transmission characteristics are evaluated as NG. Based on this comparison, it has been experimentally revealed that the deterioration of the transmission characteristics associated with the bending of cable 100 can be suppressed by setting the value obtained by dividing the hardness of first portion 11 by the hardness of second portion 12 to be greater than or equal to 1.05 and less than or equal to 1.50.

### (Fifth Loss Evaluation Test)

In the fifth loss evaluation test, the relation between the crystallite size of copper in shield layer 50 and the transmission characteristics of cable 100 is evaluated. In the fourth loss evaluation test, samples 5-1 to 5-5 are provided as samples of cable 100. As shown in Table 5, in samples 5-1 to 5-5, the crystallite size of copper in shield layer 50 varies.

TABLE 5

| | | Differential-mode | | |
|---|---|---|---|---|
| | Crystallite size | transmission loss (dB/m) | | |
| | of Cu in shield | Before | After | |
| | layer 50 (nm) | bending | bending | Evaluation |
| Sample 5-1 | 22 | −21 | −20 | OK |
| Sample 5-2 | 40 | −23 | −22 | OK |
| Sample 5-3 | 58 | −20 | −20 | OK |
| Sample 5-4 | 75 | −21 | −25 | OK |
| Sample 5-5 | 15 | −20 | −27 | NG |

In the fifth loss evaluation test, the transmission characteristics of each sample are evaluated by the same method as in the first loss evaluation test. In samples 5-1 to 5-4, the crystallite size in shield layer 50 is in a range of greater than or equal to 20 nm and less than or equal to 75 nm. On the other hand, in sample 5-5, the crystallite size in shield layer 50 is not in the range of greater than or equal to 20 nm and less than or equal to 75 nm.

In each of samples 5-1 to 5-4, the transmission characteristics are evaluated as OK. On the other hand, in sample 5-5, the transmission characteristics are evaluated as NG. Based on this comparison, it has been experimentally revealed that the deterioration of the transmission characteristics associated with the bending of cable 100 can be suppressed by setting the crystallite size in shield layer 50 to be greater than or equal to 20 nm and less than or equal to 75 nm.

In samples 5-1 to 5-3, the crystallite size in shield layer 50 is in a range of greater than or equal to 20 nm and less than or equal to 60 nm. On the other hand, in sample 5-4, the crystallite size in shield layer 50 is not in the range of greater than or equal to 20 nm and less than or equal to 60 nm. The transmission characteristics of samples 5-1 to 5-3 are superior to the transmission characteristics of sample 5-4. Based on this comparison, it has been experimentally revealed that the deterioration of the transmission characteristics associated with the bending of cable 100 can be further suppressed by setting the crystallite size in shield layer 50 to be greater than or equal to 20 nm and less than or equal to 60 nm.

It should be understood that the embodiments disclosed herein are illustrative in all respects and are not restrictive. The scope of the present invention is defined not by the above-described embodiments but by the claims, and is intended to include all modifications within the meaning and scope equivalent to the claims.

### REFERENCE SIGNS LIST

10: insulating layer, 10a: outer peripheral surface, 11: first portion, 12: second portion, 20a, 20b: signal line, 30: intermediate layer, 30a: outer peripheral surface, 40: metal oxide layer, 40a: first surface, 40b: second surface, 50: shield layer, 51: electroless plating layer, 52: electrolytic plating layer, 53: third portion, 54: fourth portion, 60: catalyst particle, 100: cable, 100A: processing target member, DR1: first direction, DR2: second direction, S1: preparation process, S2: intermediate layer forming process, S3: catalyst particle disposing process, S4: oxide layer forming process, S5: electroless plating process, S6: electrolytic plating process, S7: heat treatment process

1. A differential signal transmission cable comprising:
an insulating layer that extends in a longitudinal direction of the differential signal transmission cable;
a pair of signal lines that extend in the longitudinal direction and are embedded in the insulating layer; and
a shield layer that covers an outer peripheral surface of the insulating layer,
the shield layer including an electroless plating layer containing copper and an alloy element, and
a type and a content of the alloy element being selected such that a tensile stress acts on the shield layer.

2. The differential signal transmission cable according to claim 1, wherein
a content of copper in the shield layer is greater than or equal to 90% by mass,
the alloy element includes at least one of nickel, iron, and cobalt, and
at least one of following conditions is satisfied: a content of nickel in the shield layer is greater than or equal to 0.10% by mass and less than or equal to 3.0% by mass; a content of iron in the shield layer is greater than or equal to 0.0010% by mass and less than or equal to 0.0050% by mass; and a content of cobalt in the shield layer is greater than or equal to 0.0010% by mass and less than or equal to 0.0050% by mass.

3. The differential signal transmission cable according to claim 1, further comprising
a metal oxide layer between the insulating layer and the shield layer, wherein
in the metal oxide layer, a value obtained by dividing an atomic ratio of iron by an atomic ratio of copper is greater than or equal to 0.000010 and less than or equal to 0.00010,
in the metal oxide layer, a value obtained by dividing an atomic ratio of nickel by the atomic ratio of copper is greater than or equal to 0.000010 and less than or equal to 0.00080, and
in the metal oxide layer, a value obtained by dividing an atomic ratio of cobalt by the atomic ratio of copper is greater than or equal to 0.000010 and less than or equal to 0.00010.

4. The differential signal transmission cable according to claim 1, further comprising
a catalyst particle between the insulating layer and the shield layer, wherein
the catalyst particle contains palladium.

5. The differential signal transmission cable according to claim 1, further comprising
an intermediate layer that covers the outer peripheral surface of the insulating layer, wherein
the shield layer covers an outer peripheral surface of the intermediate layer.

6. A differential signal transmission cable comprising:
an insulating layer that extends in a longitudinal direction of the differential signal transmission cable;
a pair of signal lines that extend in the longitudinal direction and are embedded in the insulating layer; and
a shield layer that covers an outer peripheral surface of the insulating layer,
a hardness of the insulating layer being greater than or equal to 0.020 GPa, and
a hardness of the shield layer being less than or equal to 4.0 GPa.

7. The differential signal transmission cable according to claim 6, wherein
a value obtained by dividing the hardness of the shield layer by the hardness of the insulating layer is greater than or equal to 20 and less than or equal to 100.

8. The differential signal transmission cable according to claim 6, wherein
in a cross section orthogonal to the longitudinal direction, the insulating layer has a first portion that is a portion at a distance of up to 50 μm from an outer peripheral surface of each of the pair of signal lines and a second portion that is a portion at a distance of up to 50 μm from the outer peripheral surface of the insulating layer, and
a value obtained by dividing a hardness of the first portion by a hardness of the second portion is greater than or equal to 1.05 and less than or equal to 1.50.

9. A differential signal transmission cable comprising:
an insulating layer that extends in a longitudinal direction of the differential signal transmission cable;
a pair of signal lines that extend in the longitudinal direction and are embedded in the insulating layer; and
a shield layer that covers an outer peripheral surface of the insulating layer,
the shield layer containing copper, and
a crystallite size of copper in the shield layer being greater than or equal to 20 nm and less than or equal to 75 nm.
